(19) United States
(12) Patent Application Publication
(10) Pub. No.: US 2025/0309071 A1
(43) Pub. Date: Oct. 2, 2025

(54) SPACER FRAME FOR GRAPHITE THERMAL INTERFACE MATERIALS

(71) Applicant: Taiwan Semiconductor Manufacturing Company, Ltd., Hsin-Chu (TW)

(72) Inventors: Bang-Li Wu, Hsinchu City (TW); Kuan-Min Wang, Hsinchu City (TW); Chien-Chang Wang, Hsinchu City (TW); Kuo-Chin Chang, Chiayi City (TW); Kathy Wei Yan, Hsinchu (TW); Jun He, Hsinchu County (TW)

(21) Appl. No.: 18/621,250

(22) Filed: Mar. 29, 2024

(51) Int. Cl. H01L 23/495; H01L 23/373

(52) U.S. Cl. CPC H01L 23/49568; H01L 23/373

(57) ABSTRACT

One aspect of the present disclosure pertains to an integrated circuit (IC) package assembly. The IC package assembly includes a package substrate; a die mounted on the package substrate; a graphite thermal interface material (TIM) layer on the die; a spacer frame on the die and disposed along sidewalls of the graphite TIM layer; an adhesive TIM layer on the die and disposed along outer sidewalls of the spacer frame; and a metal lid on the graphite TIM layer. The spacer frame separates the adhesive TIM layer from the graphite TIM layer.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Demands for more power and more condensed chip space (e.g., in high performance computing (HPC) and artificial intelligence (AI) applications) require proportional advancements in thermal management. For example, advanced thermal interface materials (TIMs), such as graphite TIMs, are used to enhance thermal coupling between an IC die and a heat sink. Graphite TIMs have a vertically laminated structure, which facilitates good thermal conductivity in the vertical direction. Further, graphite TIMs have inherent high thermal conductivity and high compressibility. Since graphite TIMs are generally not adhesive, they are supplemented with adhesive gel TIMs to facilitate better adhesion of the graphite TIMs. However, defects may arise at the interface between these two heterogenous materials. These defects may propagate deeper into the interior of the graphite TIMs, thereby worsening the contact resistance of the graphite TIMs. Further, if the pressure applied to the graphite TIMs is too large, the excessive compression will damage the graphite material itself and thereby reduce thermal performance.

Therefore, although existing graphite TIMs in IC packages have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates an integrated circuit (IC) package assembly having a spacer frame integrated with a graphite TIM layer, according to an embodiment of the present disclosure.

FIGS. 2A, 2B, and 2C illustrate perspective, top, and side views of a spacer frame integrated with a graphite TIM layer, according to an embodiment of the present disclosure.

FIG. 3 illustrates a flow chart of a method to form an integrated circuit (IC) package assembly having a spacer frame integrated with a graphite TIM layer, in portion or in entirety, according to an embodiment of the present disclosure.

FIG. 4 illustrates process details of forming a spacer frame on a die as part of the method in FIG. 3, according to an embodiment of the present disclosure.

FIGS. 5A, 5B, 5C, 5D, 5E, and 5F illustrate various configurations of a spacer frame wrapping around a graphite TIM layer, according to various embodiments of the present disclosure.

FIG. 6D illustrates a side view of a spacer frame integrated with a graphite TIM layer, according to an embodiment of the present disclosure.

FIG. 7 illustrates a side view of an IC package assembly having a heat-spreading lid placed over a spacer frame integrated with a graphite TIM layer, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to integrated circuit (IC) package assemblies that incorporate graphite thermal interface material (TIM) layer(s) to improve heat transfer between a heat source (e.g., an IC chip or die) and a heat-spreading lid. Graphite TIMs include advantages over other types of TIMs due to its excellent thermal conductivity, high compressibility (i.e., elasticity), and high heat resistance. Further, their vertical laminated structure enhances heat transfer in the vertical direction. Graphite TIM is soft and malleable, as such, combining the graphite TIM with adhesive gel TIM may enhance the adhesion of the graphite TIM and provide the graphite TIM better structural support. For example, the adhesive gel TIM when cured become mechanically fixed to keep the graphite TIM in place and to prevent package warping. However, as described previously, defects may arise at the interface between graphite TIMs and adhesive gel TIMs. These defects may propagate deeper into the interior of the graphite TIMs, thereby worsening the contact resistance of the graphite TIMs. Further, although graphite TIM are highly compressible and have good thermal conductivity in the vertical direction, if the pressure applied is too big, the excessive compression will damage the graphite material itself and thereby reduce thermal performance.

The present disclosure describes a spacer frame that is used in conjunction with a graphite TIM layer. The spacer frame may be used alongside an adhesive gel TIM. However, in some embodiments, having the spacer frame eliminates the need for an adhesive gel TIM. However, in cases where adhesive gel TIM is still used, the spacer frame separates the graphite TIM layer from the adhesive gel TIM, thus avoiding the problem of interfacial defects between heterogenous materials. Further, the spacer frame includes a high-modulus material to protect the graphite TIM from being over-compressed. As such, the spacer frame can control how much the graphite TIM is compressed, which gives added flexibility to the design of the graphite TIM thickness. Different designs of the spacer frame may also be tailored for different needs. For example, the specific placement and/or amount of spacer may be adjusted to balance between preventing package warping, supporting graphite TIM from over-compression, and accounting space for adhesive gel TIM.

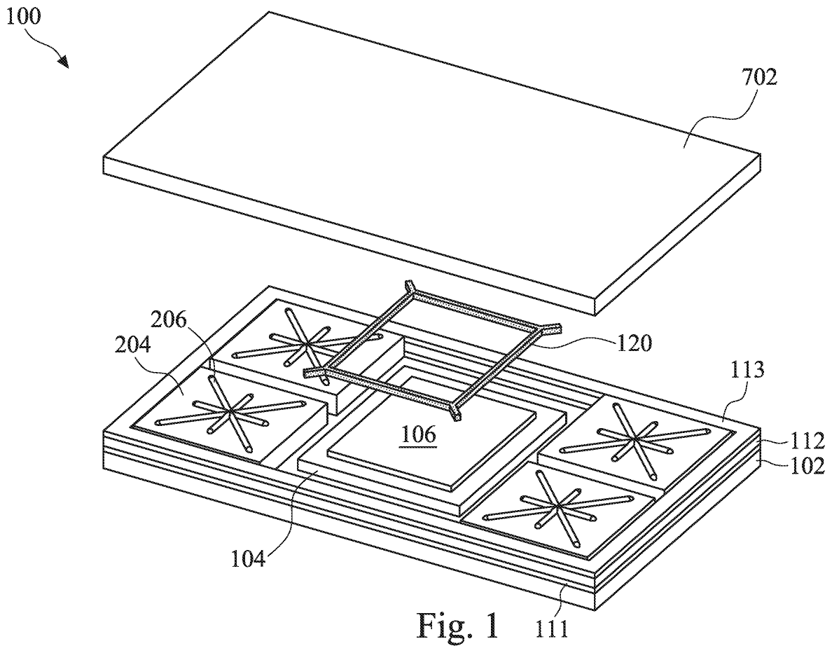

FIG. 1 illustrates an integrated circuit (IC) package assembly 100 having a spacer frame 120 integrated with a graphite TIM layer 106, according to an embodiment of the present disclosure. The IC package assembly 100 includes a package substrate 102, a die 104 mounted on the package substrate 102, a graphite TIM layer 106 on the die 104, a spacer frame 120 on the die and disposed along sidewalls of the graphite TIM layer 106, and a lid 702 over and on the graphite TIM layer 106. In the embodiment shown, the IC package assembly 100 further includes dies 204 mounted on the package substrate 102 and adhesive TIM layers 206 on the dies 204. Note that the lid 702 is also disposed over and on the adhesive TIM layer 206. The lid 702 covers the IC package assembly 100 by attaching to a perimeter frame 112 of the substrate 102. These various features are described in more detail below.

The package substrate 102 generally refers to a wafer or semiconductor structure that acts as a carrier base for an IC package. This carrier base may also be generally referred to as a base substrate, a substrate underlayer, or the like. In an embodiment, the package substrate 102 includes a semiconductor substrate formed of silicon, silicon germanium, silicon carbon, or the like. The package substrate 102 may have various package components mounted thereon, such as dies 104, dies 204, or other active or passive chip devices. The package substrate 102 may further include other package components 111 such as silicon interposers, dielectric substrates, and the like. For example, the package components 111 may include redistribution layers and/or interposers that route signals from die components onto a PCB board. In the embodiment shown, the package substrate 102 further includes a perimeter frame 112 that defines the perimeters of the package substrate 102. The perimeter frame 112 may be referred to as a part of the package substrate 102, or as a separate structure formed on a top surface of the package substrate 102. In an embodiment, the perimeter frame 112 is formed over a semiconductor material or a dielectric material of the package substrate 102. In any case, the lid 702 secures onto the perimeter frame 112 to cover the IC package assembly 100. In an embodiment, the perimeter frame 112 includes a thermally conductive material such as aluminum, copper, cobalt, or other metals. In an embodiment, the perimeter frame 112 includes similar materials as the lid 702.

Although not shown, the IC package assembly 100 may be part of a bigger IC structure. For example, the IC package assembly 100 may be mounted onto a printed circuit board (PCB). In this case, the package substrate 102 may include a ball-grid array (BGA) structure on its back side. The BGA structure includes solder joints that may bond one or more IC package assemblies 100 onto a larger PCB. The PCB may include multiple other IC components mounted thereon, thereby forming a processor, a controller, a memory unit, or other electronic modules.

Still referring to FIG. 1, the IC package assembly 100 includes dies 104 and 204. The dies 104 and 204 are mounted onto the package substrate 102. Each of the dies 104 and 204 may include various active and passive devices (e.g., transistor devices, resistors, capacitors, carrier substrate, etc.). In the embodiment shown, the dies 104 and 204 are disposed adjacent to each other in the lateral direction. In another embodiment, the dies 104 and/or 204 may be stacked on top of each other in the vertical direction. In yet another embodiment, the dies 104 and/or 204 may be disposed adjacent each other and also stacked on top of each other to form various integrated 3DIC stacked structures.

The dies 104 and 204 may be mounted onto the package substrate 102 through a controlled collapse chip connection (C4) layer. The C4 layer includes interconnect bumps such as solder bumps or copper pillar (CuP) bumps. The solder bumps may include tin, lead, and/or silver, and the CuP bumps may include a copper pillar having a solder cap at the end. The solder cap may be made of tin, lead, and/or silver. The interconnect bumps act as means for connecting a chip/die to another chip/die (when having vertically stacked dies), or to a package substrate 102 as part of an IC package assembly 100. In an embodiment, the C4 layer is disposed on a back surface of a backside interconnect structure of the dies 104 and 204. For example, the interconnect bumps are disposed on aluminum bonding pads of the backside interconnect structure. The aluminum landing pads may be part of an aluminum pad layer. And the aluminum pad layer may be part of a redistribution layer (RDL) structure. The RDL structure may include redistribution routing lines embedded in one or more passivation layers.

Each of the dies 104 and 204 may include a device layer sandwiched between various IC layers and components (e.g., sandwiched between a frontside interconnect structure and a backside interconnect structure). The device layer is where device-level features such as transistor devices are formed. The transistor devices may be logic devices, memory devices, or the like. Each of the transistor devices includes a channel region between source/drain (S/D) regions and a gate stack over the channel regions. The device layer may further include other device-level features such as S/D contacts, S/D vias, gate contacts, and/or gate vias, each of which may electrically connect the S/D regions and/or the gate stacks to a higher or lower material layer of the dies (e.g., frontside and/or backside interconnect structures). The dies 104 and 204 may include a frontside interconnect structure over the device layer and a backside interconnect structure under the device layer. The frontside and backside interconnect structures may include metal lines and vias embedded in intermetal dielectric (IMD) layers, and the metal lines and vias route signals to and from the transistor devices in the device layer. In an embodiment, as part of (or separate from) the dies 104 and 204, a bonding layer is disposed over the frontside interconnect structure, and a carrier substrate is disposed over the bonding layer. For example, the bonding layer and the carrier substrate (e.g., made of silicon) are formed to provide structural support when forming the backside interconnect structure.

In the embodiment shown, the dies 104 are distinguished from the dies 204 by the type of TIM used. For example, the dies 104 uses graphite TIM layers 106 while dies 204 uses adhesive TIM layers 206. In an embodiment, the dies 104 perform more computationally intensive tasks and require better thermal control than the dies 204. In an embodiment, the dies 104 generates more heat than the dies 204. As such, the dies 104 use graphite TIM for better thermal performance while the dies 204 use an adhesive TIM. In an embodiment, the dies 104 include high power or high speed logic or memory devices, and the dies 204 include low power or low speed logic or memory devices. In an embodiment, the dies 204 are DRAM devices.

Still referring to FIG. 1, the IC package assembly 100 includes TIM layers disposed over the dies 104 and 204. Specifically, graphite TIM layers 106 are disposed over center portions of the dies 104 (FIG. 1 shows one die 104 but there could be more), and adhesive TIM layers 206 are disposed over center portions of the dies 204. In embodiments where there are multiple stacked dies, the respective TIM layers may be disposed between the stacked dies. In any case, the respective TIM layers are disposed on a top surface of a topmost die 104 and a topmost die 204. The graphite TIM layers 106 and the adhesive TIM layers 206 act as heat conductors and distributors on a front side of the respective dies. The respective TIM layers may be configured to uniformly and effectively direct heat away from the respective dies 104 and 204 to the lid 702.

The graphite TIM layer 106 may include a graphite filler embedded in a base material, where the graphite filler has a vertically laminated structure (filler direction extends vertically). As described herein, the vertically laminated structure improves thermal distribution in the vertical direction. In alternative embodiments, the graphite filler has a horizontally laminated structure (filler direction extends horizontally). For example, since vertically laminated structures may be more sensitive to downward pressure force than horizontally laminated structures, in some cases, horizontally laminated structures are used for more force-sensitive applications. The base material of the graphite TIM layer 106 may be a polymeric material, a resin, or other suitable materials. The graphite TIM layer 106 is not adhesive and stays in place between the dies 104 and the lid 702 by compression force and/or by assistance of an adhesive TIM material (e.g., an adhesive gel TIM 116 discussed later).

The adhesive TIM layer 206 may also include a base material and a filler. However, the adhesive TIM layer 206 does not include graphite. The base material of the adhesive TIM layer 206 may include silicone, polyolefin, resin, or epoxy. The filler of the adhesive TIM layer 206 may be a dielectric filler such as aluminum oxide, magnesium oxide, aluminum nitride, boron nitride, and/or diamond powder. Alternatively, the filler of the adhesive TIM layer 206 may be a metal filler such as silver, copper, aluminum, or the like. The adhesive TIM layer 206 may be a thermal adhesive or a thermal gel that cures and becomes structurally rigid under a curing process. As such, the adhesive TIM layer 206 not only acts as a heat distributor, but also as an adhesive film to bond between the dies 204 and the lid 702.

Still referring to FIG. 1, the IC package assembly 100 further includes a lid 702 disposed on top surfaces of the graphite TIM layer 106 and the adhesive TIM layers 206. The lid 702 is secured onto the perimeter frame 112, such as through a base adhesive 113 on the top surface of the perimeter frame 112. The base adhesive 113 may include base adhesive joints or a lid seal glue layer. The base adhesive 113 be made of any suitable material (e.g., epoxy, adhesive tapes, etc.). As such, the lid 702 is directly mounted onto the perimeter frame 112 of the package substrate 102 through the base adhesive 113. Further, the lid 702 may also be adhesively bonded to the dies 204 through the adhesive TIM layers 206. In some embodiments, and as described in more detail below, an adhesive gel TIM 116 may also be disposed on the dies 104, and the lid 702 is also adhesively bonded to the dies 104 through the adhesive gel TIM 116.

The lid 702 (or metal lid 702) may be a metal cap that acts as a cover for the IC package assembly 100. Besides acting as a cover, the lid 702 also acts as a heat spreader and heat absorber to absorb any heat dissipated from components of the dies 104 and 204. The lid 702 absorbs heat from the dies 104 and 204 through the respective graphite TIM layers 106 and adhesive TIM layers 206. In embodiments where adhesive gel TIM 116 is present, the lid 702 also absorbs heat from the dies 104 from the adhesive gel TIM 116. The lid 702 is formed of a metal or a metal alloy, which has a high thermal conductivity, for example, higher than about 100 W/m/K. For example, the lid may be formed of a metal, or a metal alloy selected from Al, Cu, Ni, Co, stainless steel, and alloys thereof. In an embodiment, the lid 702 includes similar materials as the perimeter frame 112. In further embodiments, the lid 702 and the perimeter frame 112 are parts of a single lid structure, and the perimeter frame portion of the single lid structure bonds to the package substrate 102 by base adhesives 113.

Still referring to FIG. 1, the IC package assembly 100 further includes a spacer frame 120 disposed along sidewalls of the graphite TIM layer 106. If multiple graphite TIM layers 106 are present (e.g., there are multiple dies 104 on the package substrate 102), multiple spacer frames 120 correspond to each of the multiple graphite TIM layers 106. However, the dies 204 do not have corresponding spacer frames 120. This is because the spacer frame 120 is designed as a specific conjugate solution for the graphite TIM layers 106, and this solution does not apply to the adhesive TIM layers 206. For example, the spacer frame 120 protects the graphite TIM layer 106 from over-compression by having a greater elastic modulus than the graphite TIM layer 106. In an embodiment, the spacer frame 120 is a rigid material that has an elastic modulus greater than about 3000 MPa. As such, when the lid 702 presses down too hard, the lid 702 will stop compressing the graphite TIM layer 106 when it lands on the spacer frame 120. In other words, the graphite TIM layer 106 will (at the most) only press down until a height at which the lid 702 lands on the spacer frame 120. In this way, the amount of graphite TIM compression can be designed based on the height of the spacer frame 120. Further, the compression amount may be designed such that the graphite TIM layer 106 stays in place without the need of extra adhesive gel TIM 116 between the dies 104 and the lid 702. In an embodiment, the spacer frame 120 include similar materials as the perimeter frame 112 previously described.

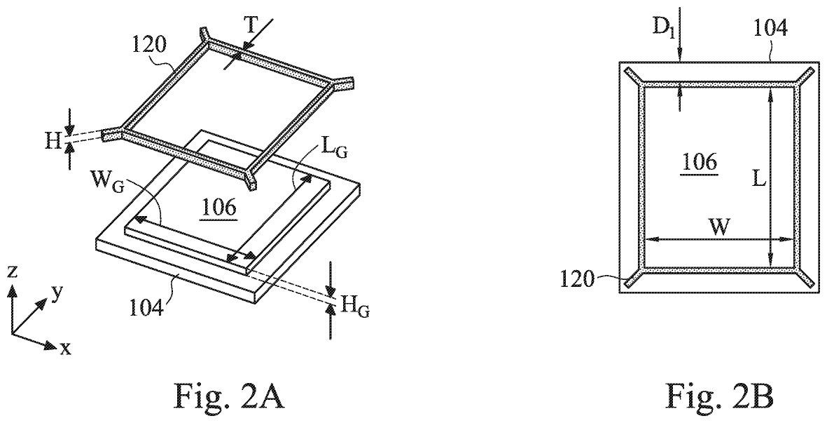

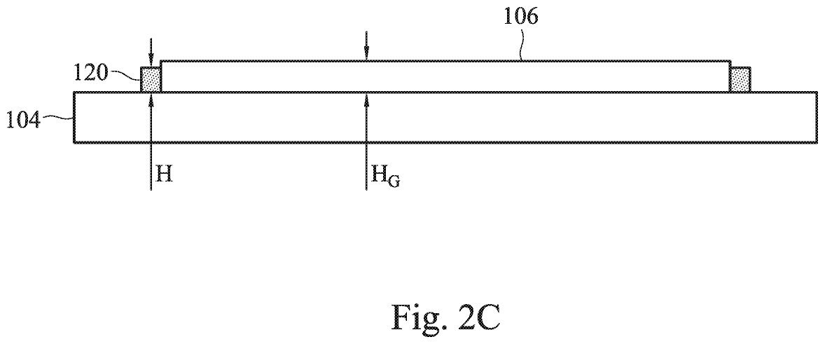

FIGS. 2A-2C illustrate perspective, top, and side views of a spacer frame 120 integrated with a graphite TIM layer 106, according to an embodiment of the present disclosure. Referring to FIG. 2A, the graphite TIM layer 106 is disposed over a center portion of a die 104. The graphite TIM layer 106 has a width W_{G} along the x direction, a length L_{G} along the y direction, and a height H_{G} along the z direction. The width W_{G} and the length L_{G} are smaller than the width and length of the die 104. As such, there are exposed portions of the die 104 that run along perimeter portions of the die 104. These exposed portions provide a perimeter spacing for the spacer frame 120 such that the spacer frame 120 may be placed on the die 104 along sidewalls of the graphite TIM layer 106. The perimeter spacing may be defined by an area between the edges of the graphite TIM layer 106 and the edges of the die 104. In an embodiment, the graphite TIM layer 106 has a width W_{G} and length L_{G} such that an area of the graphite TIM layer 106 covers at least 90% of an area of the die 104. However, the present disclosure is not limited thereto. For example, as long as the graphite TIM layer 106 completely covers hot spot areas above the die 104, the graphite TIM layer 106 may cover a smaller area of the die 104.

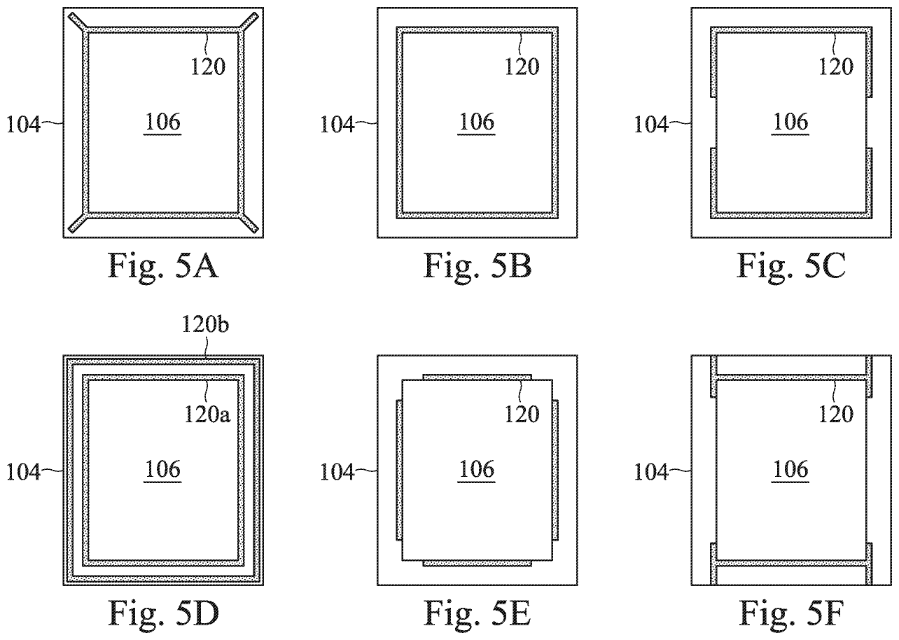

Referring to FIGS. 2A and 2B collectively, note that a distance D1 between the edges of the graphite TIM layer 106 and the edges of the die 104 is at least greater than a thickness T of the spacer frame along the lateral directions (x and y). This provides enough spacing for placing the spacer frame 120 and optionally the adhesive gel TIM 116. In an embodiment, the thickness T is designed to be as thin as possible (e.g., T<1 mm) to avoid affecting the heat dissipation of the TIM layer 106. The spacer frame 120 has a height H along the z direction, a thickness T along the x and y directions, and encloses an area having an inner length L and an inner width W. The inner length L may be equal to or greater than the length L_{G} of the graphite TIM layer 106. The inner width W may be equal to or greater than the width W_{G} of the graphite TIM layer 106. In other words, the spacer frame 120 may directly contact sidewalls of the graphite TIM layer 106 (i.e., L=L_{G} and/or W=W_{G}), or there may be some separation between the spacer frame 120 and the graphite TIM layer 106 (i.e., L>L_{G} and/or W>W_{G}). In the embodiment shown, the spacer frame 120 completely surrounds sidewalls of the graphite TIM layer 106 and include corner portions that extend diagonally from corners of the spacer frame 120. This and other designs for the spacer frame 120 will be explained in further detail with respect to FIGS. 5A-5F.

Referring to FIG. 2C, the graphite TIM layer 106 may be formed to have a height H_{G}, the spacer frame 120 may be formed to have a height H, and the height H is less than or equal to the height H_{G} (i.e., ratio of H to H_{G} is less than or equal to 1). The height H should not be greater than the height H_{G}, otherwise when the lid 702 is secured, the lid 702 only lands on the spacer frame 120 without contacting the graphite TIM layer 106. In other words, the spacer frame 120 is designed to prevent compression; therefore, if H is greater than H_{G}, the spacer frame 120 prevents the lid 702 from touching the graphite TIM layer 106. In some embodiments, some amount of compression to the graphite TIM layer 106 is needed (i.e., ratio of H to H_{G} has to be less than 1). Such compression improves surface contact and thermal flow between the die 104 and the lid 702. To facilitate compression, the height H would be smaller than the height H_{G}. In this way, when the lid 702 is secured, the graphite TIM layer 106 may be compressed downwards until it reaches the height H. However, as described herein, over-compression may damage the graphite TIM layer 106. As such, the height H should not be too small. In an embodiment, the amount of compression should not be greater than 50% the height H_{G}. This is because if there is greater than 50% compression, the graphite TIM layer 106 may be damaged. In this case, the height H should at least be greater than half of H_{G} (i.e., ratio of H to H_{G} is greater than equal to 0.5). In an embodiment, the spacer frame 120 has a height H such that 0.5*H_{G}≤H≤H_{G}. In an embodiment, the spacer frame 120 has a height H such that 0.5*H_{G}≤H<H_{G}.

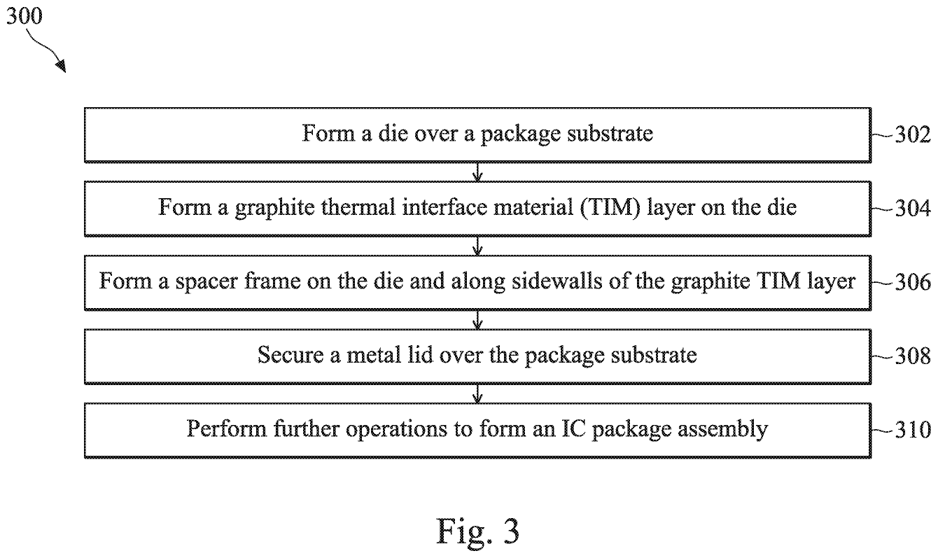

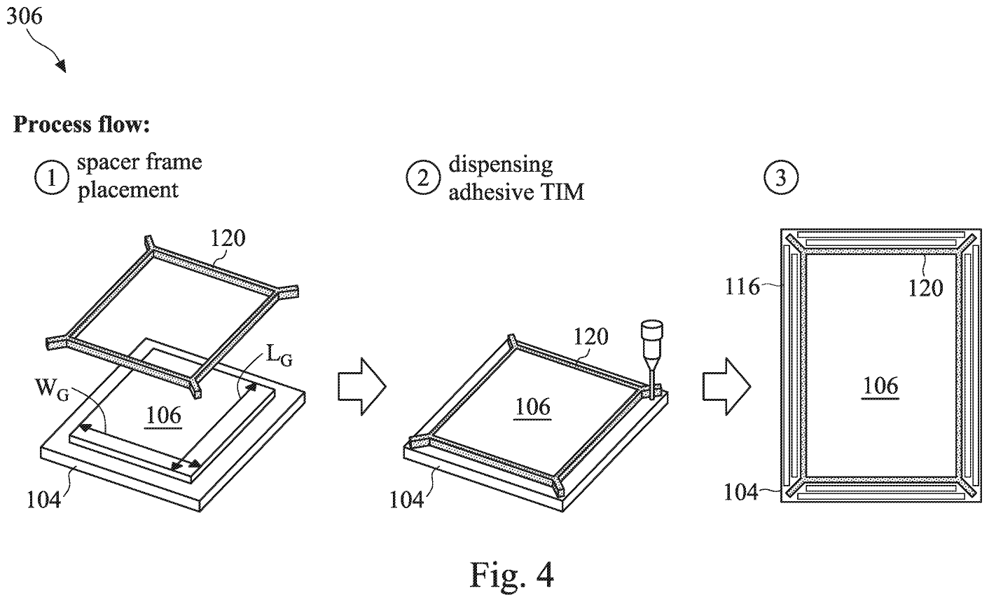

FIG. 3 illustrates a flow chart of a method 300 to form an integrated circuit (IC) package assembly 100 having a spacer frame 120 integrated with a graphite TIM layer 106, in portion or in entirety, according to an embodiment of the present disclosure. The method 300 is described with reference to FIG. 4, which depict additional process details of forming a spacer frame 120 on a die 104 as part of the method 300 in FIG. 3. Additional operations can be provided before, during, and after the method 300, and some of the operations described can be moved, replaced, or eliminated for additional embodiments of method 300. Note that the features that have been previously described with respect to FIGS. 1 and 2A-2C may be referenced in the method 300.

The method 300 at operation 302 forms a die 104 over a package substrate 102. Note that more than one die 104 may be formed over the package substrate 102, and that other dies 204 may also be formed over the package substrate 102. The dies 104 and 204 may be formed on the package substrate 102 by C4 bonding as described above.

The method 300 at operation 304 forms a graphite TIM layer 106 on the die 104. The graphite TIM layer 106 is formed to have a height H_{G}. Note that during this operation, the method 300 may also form adhesive TIM layers 206 over the dies 104. The respective TIM layers may be formed by any suitable deposition or dispensing process.

The method 300 at operation 306 forms a spacer frame 120 on the die and along sidewalls of the graphite TIM layer 106. The spacer frame 120 is formed to have a height H equal to or less than the height H_{G} for reasons previously described. Additional details of this operation step is seen in FIG. 4. As shown, the operation 306 includes placing the spacer frame 120 to at least partially surround sidewalls of the graphite TIM layer 106. In the embodiment shown, the spacer frame 120 completely surrounds the graphite TIM layer 106. When placed, the spacer frame 120 may or may not touch the side surfaces of the TIM layer 106 depending on the inner width W and inner length L of the spacer frame 120. Also in this embodiment, the operation 306 may include dispensing an adhesive gel TIM 116 adjacent the spacer frame 120 on perimeter portions of the die 104. The adhesive gel TIM 116 may include similar materials as the adhesive TIM layers 206, and the adhesive gel TIM 116 assists in the adhesion of the graphite TIM layer 106. For example, relying on mechanical compression may not be enough to keep the graphite TIM layer 106 in place. The adhesive gel TIM 116 increases adhesion for better surface contact. The adhesive gel TIM 116 may also provide additional structural support to prevent warpage issues after the adhesive gel TIM 116 is cured. However, as discussed previously, directly mixing the adhesive gel TIM 116 with the graphite TIM layer 106 may cause defects due to heterogenous interface, therefore the spacer frame 120 provides proper isolation between the TIM materials. In some embodiments, the assistance of the adhesive gel TIM 116 is not needed, and the operation 306 only includes placing the spacer frame 120.

The method 300 at operation 308 secures a metal lid 702 over the package substrate 102. The metal lid 702 may be secured onto the substrate 102 through bonding to a perimeter frame 112, fastening to the perimeter frame 112, or other means of securement. The metal lid 702 may also bond to the dies 204 through the adhesive TIM layers 206 and/or bond to the dies 104 through the adhesive gel TIMs 116 (when present). In any case, the operation 308 includes securing the metal lid 702 such that the lid directly lands on the adhesive TIM layer 206, the graphite TIM layers 106, and/or the adhesive gel TIMs 116. In an embodiment, the operation 308 includes compressing the graphite TIM layers 106 until the metal lid 702 presses against the top surface of the spacer frame 120. In this embodiment, after the securing of the metal lid 702, the height H_{G} becomes the height H due to the compression, and top surfaces of the graphite TIM layer 106 and the spacer frame 120 are substantially coplanar. In other embodiments, the spacer frame 120 is designed as a safety feature establishing the point of maximum compression. And in these embodiments, the graphite TIM layer 106 does not have to be compressed to the maximum compression point. As such, the height H_{G} may still be greater than the height H after securing the metal lid 702.

The method 300 at operation 310 performs further operations to form an IC package assembly 100. For example, a heat sink structure is formed over the metal lid 702. In an embodiment, the heat sink structure may be also secured onto the package substrate 102. For another example, another TIM layer may be formed between the metal lid and the heat sink structure. As part of operation 310, the IC package assembly 100 may be formed onto a larger PCB board. In an embodiment, the heat sink structure may be secured onto the PCB board.

FIGS. 5A-5F illustrate various configurations of a spacer frame 120 wrapping around a graphite TIM layer 106, according to various embodiments of the present disclosure. FIGS. 5A, 5B, and 5D each illustrate at least one spacer frame 120 that completely surrounds sidewalls of a graphite TIM layer 106. These designs ensure maximum support of graphite TIM from over-compression. For example, if there are any uneven compression distribution, a portion of the spacer frame 120 will always prevent that over-compression. FIGS. 5C, 5E, and 5F each illustrate a spacer frame 120 that only partially surrounds sidewalls of a graphite TIM layer 106. These designs free up more space on the dies 104 and may allow strategic placement of spacers and adhesive gel TIMs 116 to target hot spots or compression spots. In an embodiment, the adhesive gel TIMs 116 (when present) are only placed adjacent spacer portions of the spacer frame 120. That is, exposed sidewalls of the graphite TIM layer 106 do not have adjacent adhesive gel TIMs 116.

Referring now to FIG. 5A, the spacer frame 120 further includes corner portions that extend diagonally from corners of the spacer frame 120. The corner portions may extend at substantially a 45 degree angle, and they provide additional contact support between the dies 104 and the lid 702. This extra contact support may prevent bending or warping of the dies 104 and/or lid 702 when thermal or physical stress is applied. Referring now to FIG. 5B, in some embodiments, the spacer frame 120 do not include corner portions.

Referring to FIGS. 5C and 5F, corner portions of the graphite TIM layer 106 are surrounded by the spacer frame 120 while at least some of the side portions are exposed. Referring to FIG. 5C, the exposed side portions may be in the form of one or more gaps in the spacer frame 120. Referring now to FIG. 5F, the exposed side portions may span longer than in FIG. 5C, such as spanning almost an entire length or width of a TIM sidewall. Like in FIG. 5A, FIG. 5F illustrates a spacer frame 120 having corner portions that may extend from the corners of the spacer frame 120. In the embodiment shown, the corner portions extend at substantially a 90 degree angle, and they provide additional contact support between the dies 104 and the lid 702. Referring to FIG. 5E, the spacer frame 120 completely surrounds the graphite TIM layer 106 except at corner portions of the graphite TIM layer 106.

Referring now to FIG. 5D, the spacer frame 120 includes a first spacer loop 120a and a second spacer loop 120b. The first spacer loop 120a is similar to the spacer frame 120 in FIG. 5B. The first spacer loop 120a completely surrounds and may directly contact sidewalls of the graphite TIM layer 106. The second spacer loop 120b completely surrounds the first loop, where the first spacer loop 120a and the second spacer loop 120b are distanced away from each other. The space between the two loops may be filled with an adhesive gel TIM 116. Having the two loops provide benefits in both supporting the graphite TIM layer 106 from over-compression (via the first spacer loop 120a) and providing overall contact support to prevent warping issues (via the second spacer loop 120b), all the while accounting space for the adhesive gel TIM 116.

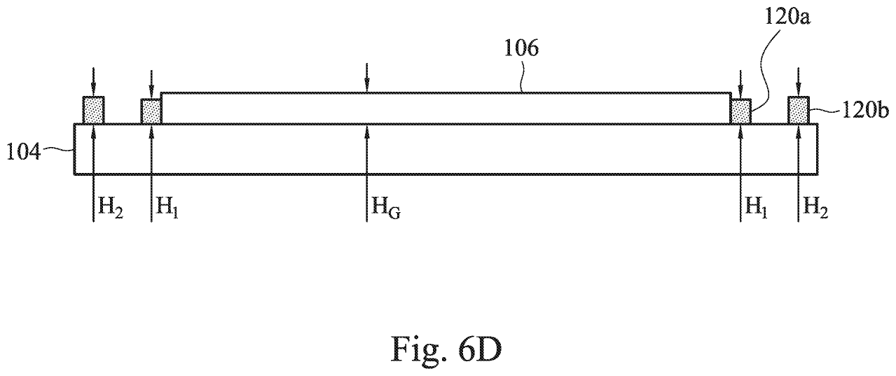

FIG. 6D illustrates a side view of a spacer frame 120 integrated with a graphite TIM layer 106, according to an embodiment of the present disclosure. Specifically, FIG. 6D corresponds to the spacer frame configuration in FIG. 5D, which includes a first spacer loop 120a and a second spacer loop 120b. In this configuration, the first spacer loop 120a has a height H₁, the second spacer loop 120b has a height H₂, and the height H₂ is greater than or equal to the height H₁. The height H₂ may be greater than the height H₁ due to more warping concerns towards the edges of the die 104 when the lid 702 is secured over the graphite TIM layer 106. For example, more physical and thermal stress will be applied to the top surface of the second spacer loop 120b as compared to the top surface of the first spacer loop 120a. As such, the second spacer loop 120b may be designed to have a greater height H₂ for cushioning purposes, while the first spacer loop 120a need only sufficient height to prevent over-compression of the graphite TIM layer 106. In an embodiment, the spacer frame 120 has a H₁ and H₂ such that 0.5*H_{G}≤H₁≤H₂≤H_{G}. Note that in the present embodiments, the height H_{G} refer to the height of the graphite TIM layer 106 before compression (i.e., before the lid 702 is secured). After compression, the height H_{G} may decrease down to a height H, H₁, or H₂.

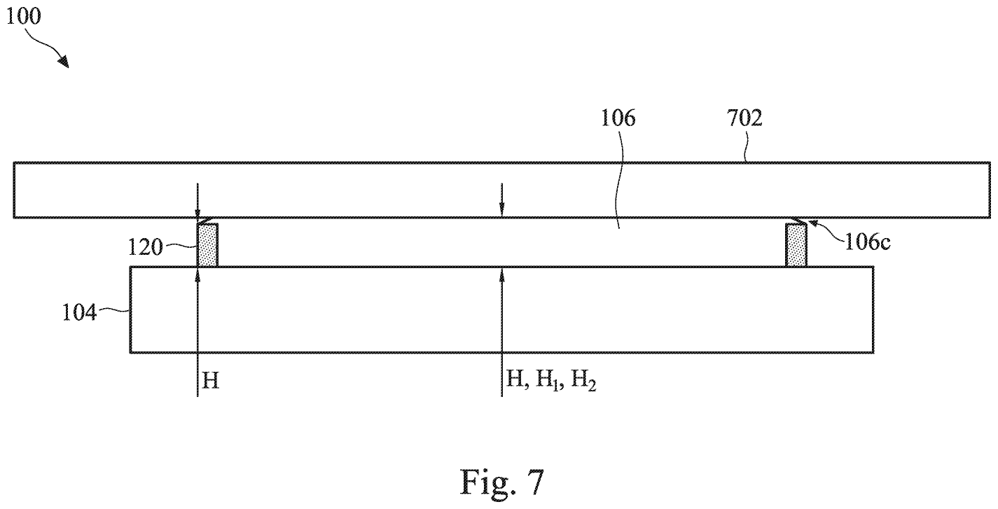

FIG. 7 illustrates a side view of an IC package assembly (e.g., a portion of IC package assembly 100 in FIG. 1) having a heat-spreading lid 702 placed over a spacer frame 120 integrated with a graphite TIM layer 106. As shown, after the lid 702 is secured onto the graphite TIM layer 106, the graphite TIM layer 106 may be compressed from the height H_{G} to a height H, H₁, or H₂ as described herein. Note that in some embodiments and as shown in FIG. 7, due to the compression of the graphite TIM layer 106, upper corner portions 106c of the graphite TIM layer 106 may be squeezed to laterally extend over a top surface of the spacer frame 120. In other embodiments (not shown), the upper corner portions 106c are avoided by leaving more space between sidewalls of the spacer frame 120 and sidewalls of the graphite TIM layer 106. The extra space may account for possible lateral spread of the graphite TIM layer 106 after the heat-spreading lid 702 is secured onto the graphite TIM layer 106.

Although not limiting, the present disclosure offers advantages for IC package assemblies. One example advantage is to incorporate spacer frames to improve the weakness of graphite as a package TIM material. Another example advantage is having the spacer frame surround the graphite TIM to control graphite TIM thickness (or referred to as heights) and to prevent over-compression. Another example advantage is to incorporate the spacer frames with adhesive gel TIMs to improve adhesion and help control package warpage. Another example advantage is to use the spacer frames to separate the graphite TIM from the adhesive gel TIM to avoid interfacial defects between heterogenous materials. Another example advantage is having various types of spacer frame configurations according to design needs.

One aspect of the present disclosure pertains to an integrated circuit (IC) package assembly. The IC package assembly includes a package substrate; a die mounted on the package substrate; a graphite thermal interface material (TIM) layer on the die; a spacer frame on the die and disposed along sidewalls of the graphite TIM layer; an adhesive TIM layer on the die and disposed along outer sidewalls of the spacer frame; and a metal lid on the graphite TIM layer. The spacer frame separates the adhesive TIM layer from the graphite TIM layer.

In an embodiment, the adhesive TIM layer is a thermal gel or a thermal adhesive having a base material and a filler. The base material includes silicone, polyolefin, resin, or epoxy. The filler includes aluminum oxide, magnesium oxide, aluminum nitride, boron nitride, or diamond powder.

In an embodiment, the IC package assembly further includes a base adhesive on a perimeter frame of the package substrate. The metal lid is secured onto the perimeter frame through the base adhesive. The metal lid is secured onto the die through the adhesive TIM layer.

In an embodiment, the metal lid directly lands on the graphite TIM layer and the spacer frame.

In an embodiment, the spacer frame encloses an area having an inner length and an inner width. The inner length is greater than a length of the graphite TIM layer, and the inner width is greater than a width of the graphite TIM layer.

In an embodiment, the spacer frame has a greater elastic modulus than the graphite TIM layer.

In an embodiment, the spacer frame completely surrounds the graphite TIM layer except at corner portions of the graphite TIM layer.

In an embodiment, the spacer frame includes: a first loop that completely surrounds the graphite TIM layer; and a second loop that completely surrounds the first loop, wherein the first and the second loops are distanced away from each other.

In an embodiment, the graphite TIM layer includes a graphite filler embedded in a base material, and the graphite filler has a vertically laminated structure.

Another aspect of the present disclosure pertains to an integrated circuit (IC) package assembly. The IC package assembly includes a package substrate; a first die mounted on the package substrate; a first thermal interface material (TIM) layer disposed on a center portion of the first die; a spacer frame disposed on perimeter portions of the first die and along sidewalls of the first TIM layer; a second die mounted on the package substrate; a second TIM layer disposed on a center portion of the second die; and a metal lid disposed on the first and the second TIM layers. The first TIM layer and the second TIM layer include different materials.

In an embodiment, the first TIM layer includes graphite, and the second TIM layer includes aluminum, magnesium, boron, diamond, or silver.

In an embodiment, the IC package assembly further includes an adhesive gel disposed on the first die along outer sidewalls of the spacer frame. The spacer frame separates the adhesive gel from the first TIM layer. The adhesive gel glues the metal lid to the first die.

In an embodiment, top surfaces of the first TIM layer and the spacer frame is substantially coplanar.

In an embodiment, the spacer frame completely surrounds the first TIM layer. In a further embodiment, the spacer frame include corner portions that extend diagonally from corners of the spacer frame.

In an embodiment, the spacer frame only partially surrounds the first TIM layer.

Another aspect of the present disclosure pertains to a method of forming an integrated circuit (IC) package assembly. The method includes forming a die over a package substrate; forming a graphite thermal interface material (TIM) layer on the die; forming a spacer frame on the die and along sidewalls of the graphite TIM layer; and securing a metal lid over the package substrate, where the metal lid directly lands on a top surface of the graphite TIM layer and the spacer frame.

In an embodiment, the forming of the spacer frame further includes placing the spacer frame to at least partially surround sidewalls of the graphite TIM layer; and dispensing an adhesive TIM adjacent the spacer frame on perimeter portions of the die.

In an embodiment, the graphite TIM layer is formed to have a first height, the spacer frame is formed to have a second height, and the first height is greater than the second height. In a further embodiment, the securing of the metal lid includes compressing the graphite TIM layer until the metal lid presses against the top surface of the spacer frame, where after the securing of the metal lid, the first height becomes the second height.

The details of the method and device of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) package assembly, comprising:
a package substrate;
a die mounted on the package substrate;
a graphite thermal interface material (TIM) layer on the die;
a spacer frame on the die and disposed along sidewalls of the graphite TIM layer;
an adhesive TIM layer on the die and disposed along outer sidewalls of the spacer frame; and
a metal lid on the graphite TIM layer, wherein the spacer frame separates the adhesive TIM layer from the graphite TIM layer.

2. The IC package assembly of claim 1,
wherein the adhesive TIM layer is a thermal gel or a thermal adhesive having a base material and a filler,
wherein the base material includes silicone, polyolefin, resin, or epoxy,
wherein the filler includes aluminum oxide, magnesium oxide, aluminum nitride, boron nitride, or diamond powder.

3. The IC package assembly of claim 1, further comprising: a base adhesive on a perimeter frame of the package substrate,
wherein the metal lid is secured onto the perimeter frame through the base adhesive,
wherein the metal lid is secured onto the die through the adhesive TIM layer.

4. The IC package assembly of claim 1, wherein the metal lid directly lands on the graphite TIM layer and the spacer frame.

5. The IC package assembly of claim 1,
wherein the spacer frame encloses an area having an inner length and an inner width,
wherein the inner length is greater than a length of the graphite TIM layer, and the inner width is greater than a width of the graphite TIM layer.

6. The IC package assembly of claim 1, wherein the spacer frame has a greater elastic modulus than the graphite TIM layer.

7. The IC package assembly of claim 1, wherein the spacer frame completely surrounds the graphite TIM layer except at corner portions of the graphite TIM layer.

8. The IC package assembly of claim 1, wherein the spacer frame includes:
a first loop that completely surrounds the graphite TIM layer; and
a second loop that completely surrounds the first loop, wherein the first and the second loops are distanced away from each other.

9. The IC package assembly of claim 1, wherein the graphite TIM layer includes a graphite filler embedded in a base material, and the graphite filler has a vertically laminated structure.

10. An integrated circuit (IC) package assembly, comprising:
a package substrate;
a first die mounted on the package substrate;
a first thermal interface material (TIM) layer disposed on a center portion of the first die;
a spacer frame disposed on perimeter portions of the first die and along sidewalls of the first TIM layer;
a second die mounted on the package substrate;
a second TIM layer disposed on a center portion of the second die; and
a metal lid disposed on the first and the second TIM layers, wherein the first TIM layer and the second TIM layer include different materials.

11. The IC package assembly of claim 10, wherein the first TIM layer includes graphite, and the second TIM layer includes aluminum, magnesium, boron, diamond, or silver.

12. The IC package assembly of claim 10, further comprising:
an adhesive gel disposed on the first die along outer sidewalls of the spacer frame, wherein the spacer frame separates the adhesive gel from the first TIM layer, wherein the adhesive gel glues the metal lid to the first die.

13. The IC package assembly of claim 10, wherein top surfaces of the first TIM layer and the spacer frame is substantially coplanar.

14. The IC package assembly of claim 10, wherein the spacer frame completely surrounds the first TIM layer.

15. The IC package assembly of claim 14, wherein the spacer frame include corner portions that extend diagonally from corners of the spacer frame.

16. The IC package assembly of claim 10, wherein the spacer frame only partially surrounds the first TIM layer.

17. A method of forming an integrated circuit (IC) package assembly, comprising:
forming a die over a package substrate;
forming a graphite thermal interface material (TIM) layer on the die;
forming a spacer frame on the die and along sidewalls of the graphite TIM layer; and
securing a metal lid over the package substrate, wherein the metal lid directly lands on a top surface of the graphite TIM layer and the spacer frame.

18. The method of claim 17, wherein the forming of the spacer frame further includes:
placing the spacer frame to at least partially surround sidewalls of the graphite TIM layer; and
dispensing an adhesive TIM adjacent the spacer frame on perimeter portions of the die.

19. The method of claim 18,
wherein the graphite TIM layer is formed to have a first height, the spacer frame is formed to have a second height, and the first height is greater than the second height.

20. The method of claim 19,
wherein the securing of the metal lid includes compressing the graphite TIM layer until the metal lid presses against the top surface of the spacer frame,
wherein after the securing of the metal lid, the first height becomes the second height.
